(19) United States
(12) Patent Application Publication
(10) Pub. No.: US 2026/0182297 A1
(43) Pub. Date: Jun. 25, 2026

(54) MASS TRANSFER EQUIPMENT

(71) Applicant: PlayNitride Display Co., Ltd., Miaoli County (TW)

(72) Inventors: Yen-Mu CHEN, Miaoli County (TW); Hung-Ming CHIU, Miaoli County (TW); Han-Cheng TSOU, Miaoli County (TW); Chung-Wei TSAI, Miaoli County (TW)

(21) Appl. No.: 19/088,121

(22) Filed: Mar. 24, 2025

(30) Foreign Application Priority Data
Dec. 19, 2024 (TW) 113149745

(51) Int. Cl. H01L 21/67; G01S 17/08; H01L 21/683

(52) U.S. Cl. CPC H10P 72/0446; G01S 17/08; H10P 72/0606; H10P 72/74; H10P 72/7434

(57) ABSTRACT

A mass transfer equipment is suitable for transferring microchips from a component substrate on a first carrier stage to a target substrate on a second carrier stage. Corresponding areas on the component substrate and the target substrate are departed by a distance in a second direction. An actuating unit controls the first and/or the second carrier stages to move. A rangefinder measures a movement of the component substrate in a first direction to obtain a first variation information and a movement of the target substrate in the first direction to obtain a second variation information. The first and the second variation information respectively include vectors of the corresponding areas on the component substrate and the target substrate in the second direction. A processing unit obtains a compensation value for changing the distance based on the first and/or the second variation information.

### CROSS REFERENCE TO RELATED APPLICATIONS

This Non-provisional application claims priority under 35 U.S.C. § 119(a) on Patent Application No(s). 113149745 filed in Taiwan, Republic of China on 19 Dec. 2024, the entire contents of which are hereby incorporated by reference.

### BACKGROUND

### Technology Field

The present disclosure relates to transfer equipment and, in particular, to mass transfer equipment for micro components.

### Description of Related Art

Mass transfer is regarded as a critical technology for achieving mass production of micro light-emitting diodes (Micro LEDs) and an important factor affecting process yield, so many manufacturers have invested in the development of mass transfer technology. Mass transfer technology is mainly divided into two modes: stamp transfer and laser transfer. At present, most manufacturers choose the stamp transfer method, which uses the imprint head to apply pressing force on the chip, attaches the chip to the imprint head by Van der Waals force, and then moves the chip to a specific position on the substrate to bond to the contact pads on the substrate, thereby finishing the transfer process. The stamp transfer technology is relatively mature and the equipment cost is relatively cheap, but has the drawback of lower transfer efficiency. Therefore, more and more equipment manufacturers are turning their attention to the laser transfer technology.

The speed of laser transfer is much faster than that of mechanical transfer method (e.g. the stamp transfer). In the laser transfer method, the component substrate is configured with an adhesive layer and microchips, and the component substrate is located on one side of the upper carrier stage facing the lower carrier stage. The target substrate is located on one side of the lower carrier stage facing the upper carrier stage. The laser beam is provided to irradiate the adhesive layer, and the material of the adhesive layer can absorb the energy of the laser beam and then be rapidly evaporated, thereby removing the adhesive layer between the chips and the component substrate. Afterwards, the chips can be peeled off and dropped to the corresponding positions on the target substrate, thereby finishing the transfer process of the chips.

When using the laser transfer method for transferring micro components, in order to perform the dynamic, real-time and on-the-fly mass transfer, the dynamic parallelism and spacing between the upper carrier stage for carrying the component substrate and the lower carrier stage for carrying the target substrate need to be controlled within the range of microns to ensure transfer accuracy and yield. However, the currently commercially available transfer equipment that meets this condition is very expensive, and the price may double as the carrier stages are larger.

### SUMMARY

An objective of this disclosure is to provide dynamic, real-time and on-the-fly mass transfer equipment that can provide the dynamic and real-time compensation in the height direction to the transfer system. Therefore, when applied to a mass transfer stage system with lower flatness and cheaper price, the present disclosure can still achieve the effect of stabilizing the height of the spacing between the substrates.

This disclosure is not limited by the size of the carrier stages, and can be applied to the large-sized carrier stages for performing mass transfer processes, thereby reducing the cost of transfer equipment.

To achieve the above, the mass transfer equipment of this disclosure is suitable for transferring a plurality of microchips from a component substrate to a target substrate, and includes a first carrier stage, a second carrier stage, an actuating unit, a rangefinder, and a processing unit. The first carrier stage is configured for carrying the component substrate, and the first carrier stage is movable in a first direction. The second carrier stage is disposed opposite to the first carrier stage and configured for carrying the target substrate. The second carrier stage is movable in the first direction, and at least one area on the component substrate and a corresponding area on the target substrate are departed by a distance in a second direction. The actuating unit is connected with the first carrier stage and the second carrier stage, and configured for controlling at least one of the first carrier stage and the second carrier stage to move and/or rotate. The rangefinder is configured for measuring a movement of the component substrate in the first direction to obtain a first variation information and a movement of the target substrate in the first direction to obtain a second variation information. The first variation information includes a vector of the area on the component substrate in the second direction, and the second variation information includes a vector of the corresponding area on the target substrate in the second direction. The processing unit is electrically connected with the actuating unit and the rangefinder. The processing unit obtains a compensation value based on the first variation information and/or the second variation information. During the actuating unit controlling the first carrier stage or the second carrier stage to move in the first direction, the processing unit further transmits the compensation value to the actuating unit, so that the actuating unit changes the distance in accordance with the compensation value.

As mentioned above, the mass transfer equipment of this disclosure includes the actuating unit configured for changing the distance in accordance with the compensation value, so that this disclosure can perform real-time dynamic compensation in the height (Z-axis) direction of the component substrate and/or the target substrate during the dynamic, real-time and on-the-fly transfer process of microchips, thereby compensating for the flatness of the equipment. Therefore, the mass transfer equipment of this disclosure can be applied to a mass transfer stage system with lower flatness and cheaper price, and can still achieve the effect of stabilizing the height of the spacing (in the Z-axis) between two substrates. Moreover, the present disclosure is not limited by the size of the carrier stages, and can be applied to the large-sized carrier stages for performing the mass transfer process of microchips, thereby reducing the cost of transfer equipment.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing the mass transfer equipment in accordance with an embodiment of this disclosure;

FIGS. 2A and 2B are different sectional views of the mass transfer equipment of FIG. 1 during the mass transfer process;

FIG. 3 is a block diagram of the mass transfer equipment of FIG. 1; and

FIGS. 4A to 4E are schematic diagrams showing different aspects of the dynamic compensation during the transfer process of microchips.

### DETAILED DESCRIPTION OF THE DISCLOSURE

The present disclosure will be apparent from the following detailed description, which proceeds with reference to the accompanying drawings, wherein the same references relate to the same elements.

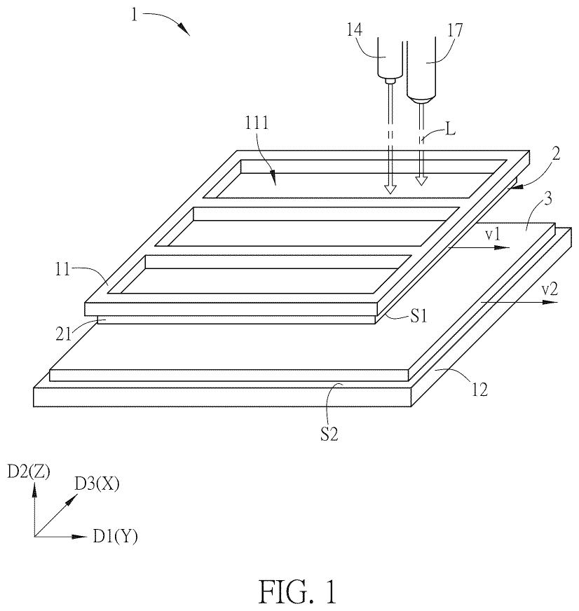

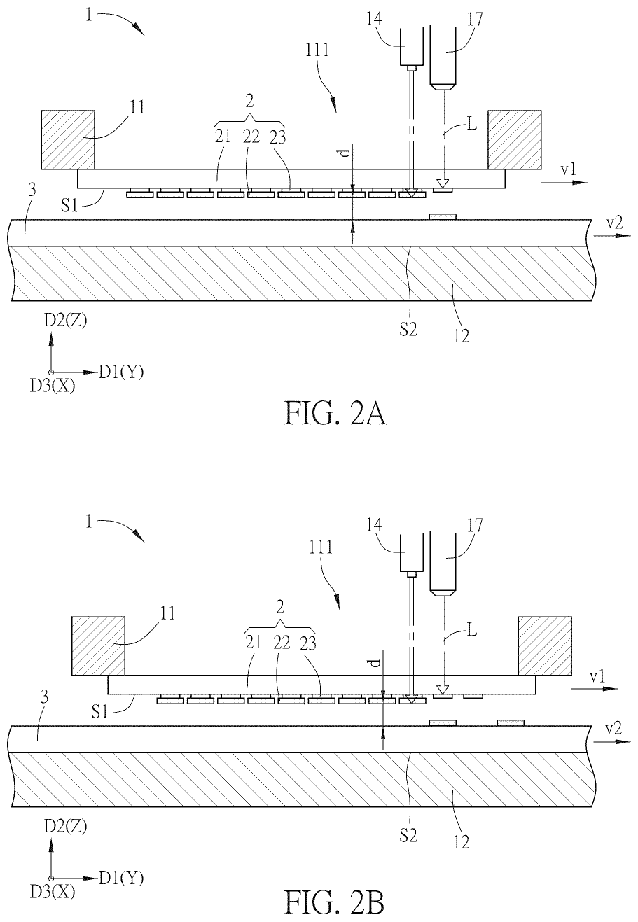

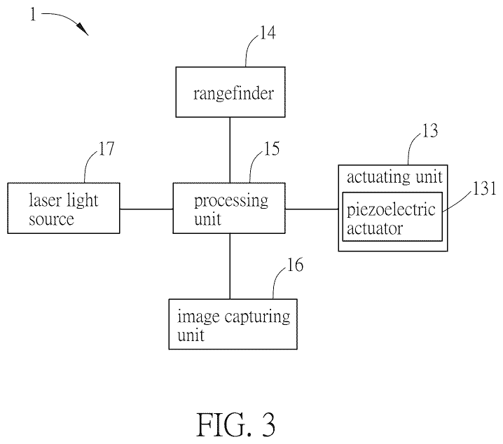

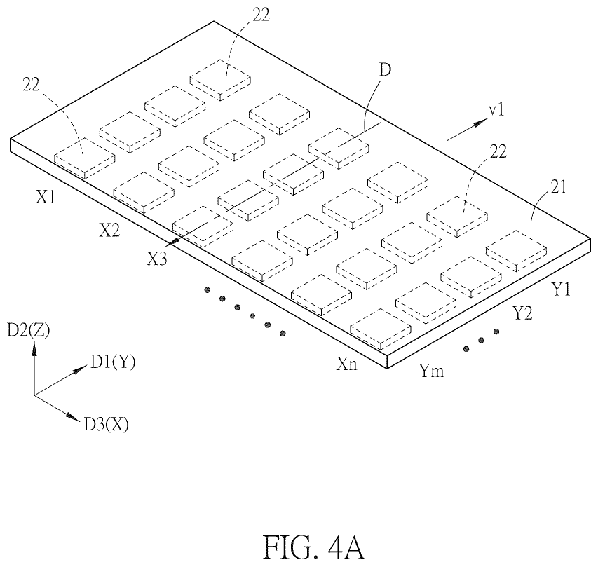

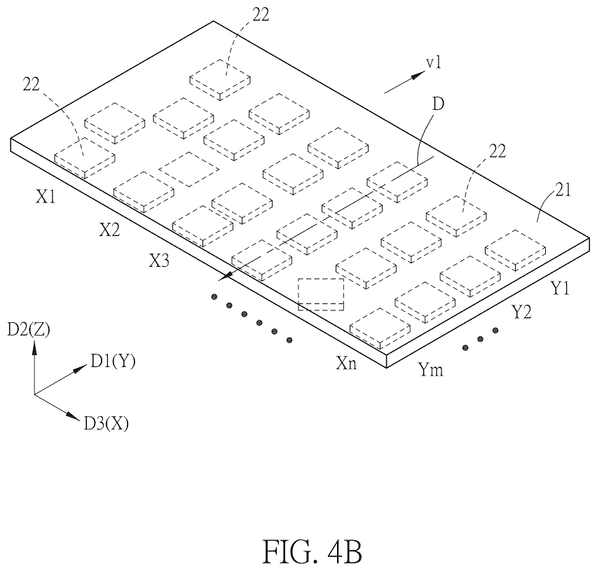

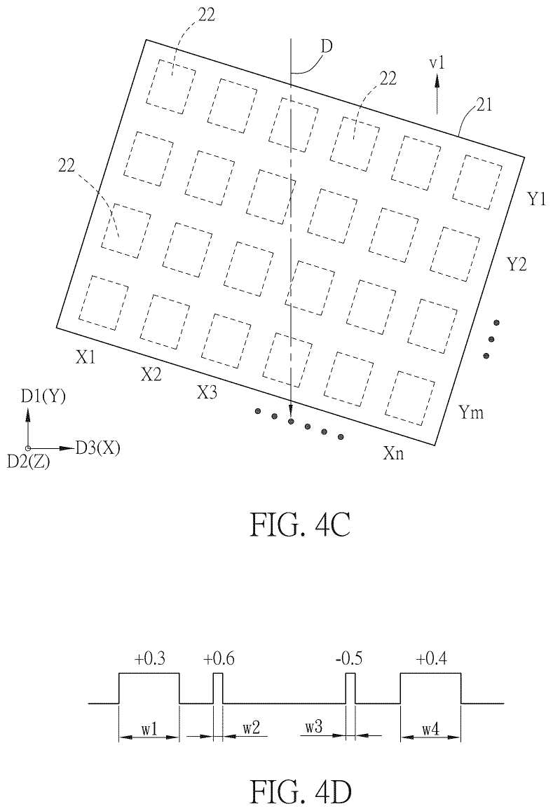

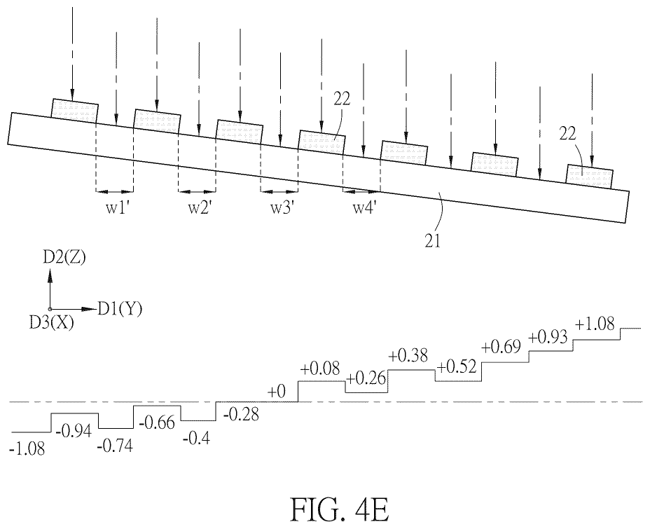

FIG. 1 is a schematic diagram showing the mass transfer equipment in accordance with an embodiment of this disclosure. FIGS. 2A and 2B are different sectional views of the mass transfer equipment of FIG. 1 during the mass transfer process. FIG. 3 is a block diagram of the mass transfer equipment of FIG. 1. FIGS. 4A to 4E are schematic diagrams showing different aspects of the dynamic compensation during the transfer process of microchips.

To be noted, FIG. 1, FIGS. 2A to 2B, and FIG. 4A to 4E illustrate a first direction D1, a second direction D2 and a third direction D3. The first direction D1, the second direction D2 and the third direction D3 are substantially perpendicular to one another. In order to clearly illustrate this disclosure, in this embodiment, the first direction D1 indicates the horizontal direction (e.g. the Y-axis direction), the second direction D2 indicates the vertical direction (e.g. the Z-axis direction, which can be realized as the height direction), and the third direction D3 indicates another horizontal direction (e.g. the X-axis direction). In addition, the symbol D in FIGS. 4A to 4C indicates the ranging direction of the rangefinder 14. Moreover, for the sake of clarity illustration, the processing unit 15 of FIG. 3 and the connection relationship between the processing unit 15 and other components are not shown in FIGS. 1, 2A and 2B, and the image capturing unit 16 is not shown in FIGS. 1, 2A and 2B.

Referring to FIGS. 1 to 3, the mass transfer equipment 1 is configured for transferring a plurality of microchips 22 provided on a component substrate 2 to a target substrate 3. The component substrate 2 of this embodiment includes a substrate 21, a plurality of microchips 22 disposed on the surface S1 of the substrate 21, and an adhesive layer 23 (e.g. a release film) located between the substrate 21 and the microchips 22. For example, the substrate 21 can be a temporary carrier, such as a glass substrate or a flexible substrate, during the transfer process, and the microchips 22 can be micro light-emitting elements disposed on the temporary carrier. The micro light-emitting elements can be, for example but not limited to, micro LED chips, which may include single-colored or multi-colored micro LED chips (e.g. red, green and blue micro LED chips). In other embodiments, the substrate 21 may be an epitaxial substrate, and the microchips 22 can be micro light-emitting chips or electronic elements that can perform predetermined electronic functions (e.g. diodes, transistors, ICs, or the likes) or photonic functions (e.g. LED, laser, or the likes). In addition, the target substrate 3 can be, for example but not limited to, a circuit backboard of a display panel. In other embodiments, the target substrate 3 can be a temporary substrate formed by stacking a carrier board and an adhesive layer.

The mass transfer equipment 1 includes a first carrier stage 11, a second carrier stage 12, an actuating unit 13, a rangefinder 14, and a processing unit 15. In addition, the mass transfer equipment 1 may further include an image capturing unit 16 and a laser light source 17.

The first carrier stage 11 is configured for carrying the component substrate 2 and is movable in the first direction D1 (Y-axis), and the second carrier stage 12 is disposed opposite to and parallel to the first carrier stage 11 and is configured for carrying the target substrate 3. The second carrier stage 12 is movable in the first direction D1 (Y-axis). In this embodiment, the component substrate 2 is disposed on the lower side of the first carrier stage 11 facing the second carrier stage 12. In this component substrate 2, the microchips 22 are disposed on the surface S1 of the substrate 21 facing the target substrate 3. The target substrate 3 is provided on the surface S2 of the second carrier stage 12 facing the microchips 22. At least one area on the component substrate 2 and a corresponding area on the target substrate 3 are departed by a distance d in the second direction D3 (Z-axis direction or height direction). Specifically, one area on the component substrate 2 may be configured with at least one microchip 22, and the distance d is defined between the microchip 22 disposed in the area on the component substrate 2 and the corresponding area (a transfer position or transfer coordinates) of the target substrate 3 in the second direction D2 (Z-axis).

The actuating unit 13 is connected with the first carrier stage 11 and the second carrier stage 12, and is configured for controlling a motion of at least one of the first carrier stage 11 and the second carrier stage 12. For example, the actuating unit 13 may controls at least one of the first carrier stage 11 and the second carrier stage 12 to move and/or rotate. In this embodiment, the actuating unit 13 can control the first carrier stage 11 and the second carrier stage 12 to move simultaneously, or the actuating unit 13 can individually control either the first carrier stage 11 or the second carrier stage 12 to move. Since the first carrier stage 11 carries the component substrate 2 and the second carrier stage 12 carries the target substrate 3, when the actuating unit 13 controls the first carrier stage 11 and/or the second carrier stage 12 to move in the first direction D1 (Y-axis), the component substrate 2 and/or the target substrate 3 can be moved in the first direction D1 (Y-axis) accordingly. It should be noted that, as shown in FIG. 2, the moving speed v1 or the moving period of the first carrier stage 11 may be the same as or different from the moving speed v2 or the moving periods of the second carrier stage 12. The moving speeds can be different (v1≠v2) or the moving periods of the first carrier stage 11 and the second carrier stage 12 can be individually determined so as to adjust the pitches of the microchips 22 transferred to the target substrate 3. In one embodiment, in order to increase the alignment accuracy between the component substrate 2 and/or the target substrate 3, the rangefinder 14 and the laser light source 17, the actuating unit 13 may further include, for example, a stepper motor, a servo motor and/or as linear guides for controlling the movement of the first carrier stage 11 and/or the second carrier stage 12 in the three-dimensional directions.

The rangefinder 14 is configured for measuring a movement of the component substrate 2 in the first direction D1 (Y-axis) to obtain a first variation information and a movement of the target substrate 3 in the first direction D1 (Y-axis) to obtain a second variation information. The first variation information includes a vector of the area on the component substrate 2 in the second direction D2 (Z-axis), and the second variation information includes a vector of the corresponding area on the target substrate 3 in the second direction D2 (Z-axis). In this embodiment, the first variation information is the displacement of at least one microchip 22 disposed in the area on the component substrate 2 relative to the first carrier stage 11 in the second direction D2 (Z-axis). The object to be measured by the rangefinder 14 in this embodiment is the distance between the microchip 22 on the component substrate 2 and the corresponding area on the target substrate 3. Since the height difference between the first carrier stage 11 and the second carrier stage 12 is known, if the distance d between the microchip 22 on the substrate 21 and the transfer position (the transfer coordinates or the corresponding area on the second carrier stage 12) can be measured by the rangefinder 14, the current height difference (the distance d in the second direction D2) between the microchip 22 and the corresponding one of the transfer coordinates can be obtained.

In one embodiment, the rangefinder 14 can be, for example but not limited to, a laser rangefinder, such as a single-point scan mode rangefinder or a line scan mode rangefinder. In the single-point scan mode, the rangefinder 14 can output a light beam to scan a certain coordinate point in the X-axis direction (the third direction D3). For example, as shown in FIG. 4A, m*n microchips 22 are arranged in a matrix at intervals along the first direction D1 (Y-axis) and the third direction D3 (X-axis), and the sampling data in the single-point scan mode can be the height change of the specific point Xj in the second direction D2 (Z-axis). For example, when j=3, the sampling data is the collection of heights in the Z-axis direction including (Y1, X3), (Y2, X3), . . . , and (Ym, X3). In the line scan mode, each sampling involves the coordinate points X1 to Xj, so the sampling data includes (Y1, avg(X1˜Xn)), (Y2, avg(X1˜Xn)), . . . , and (Ym, avg(X1˜Xn)), wherein avg( ) is used to calculate the arithmetic mean. To be noted, other sampling methods, such as mode average, median or quartile average, or the likes, are also possible, and the sampling method is not limited in this disclosure.

In this embodiment, the rangefinder 14 is disposed at one side of the first carrier stage 11 away from the second carrier stage 12 in the second direction D2 (Z-axis). That is, the first carrier stage 11 is disposed at the upper side of the second carrier stage 12 in the second direction D2. With relative to the first carrier stage 11 and the second carrier stage 12, the rangefinder 14 is fixed, and the fixing method thereof is not limited. To be noted, the fixing method is not shown. In addition, the first carrier stage 11 of this embodiment is configured with at least one opening 111 corresponding to the component substrate 2, so that the light beam emitted by the rangefinder 14 can pass through the opening 111 to irradiate the microchip 22 of the component substrate 2. To be understood, the number of the openings 111 of the first carrier stage 11 and the number of component substrates 2 carried thereon can be modified in accordance with actual process requirements.

The laser light source 17 is disposed at the same side of the first carrier stage 11 and the second carrier stage 12 in the second direction D2 (Z-axis), and the laser light source 17 has a light axis L. In this embodiment, the laser light source 17 is disposed adjacent to the rangefinder 14 in the first direction D1 (Y-axis), and is electrically connected to the processing unit 15. With respective to the first carrier stage 11 and the second carrier stage 12, the laser light source 17 is fixed, and the fixing method thereof is not limited (the fixing method is not shown). In one embodiment, the actuating unit 13 can control the first carrier stage 11 and the second carrier stage 12 to move synchronously in the first direction D1 (Y-axis), and align the aforementioned area on the first carrier stage 11 with the light axis L. Therefore, the laser light emitted by the laser light source 17 can focus on the area on the component substrate 2 so as to release at least one microchip 22, which is to be transferred to the target substrate 3, from the substrate 21. Then, the released microchip 22 can be dropped to connect with the target substrate 3. More specifically, the mass transfer equipment 1 of this embodiment adapts the laser lift-off (LLO) technology to carry out the transfer process of microchips 22. In order to achieve the laser lift-off effect, the adhesiveness of the adhesive layer 23 (e.g. the release layer) can be eliminated after irradiated by the focused laser beam, but the disclosure is not limited thereto.

The processing unit 15 is electrically connected to the actuating unit 13 and the rangefinder 14. The processing unit 15 can obtain a compensation value based on the first variation information, which is obtained based on the movement of the component substrate 2 in the first direction D1 (Y-axis), and/or the second variation information, which is obtained based on the movement of the target substrate 3 in the first direction D1 (Y-axis). The obtained compensation value represents the variations of the distance d. For example, the processing unit 15 can be a microcontroller unit (MCU). In this case, the processing unit 15 can receive the set-up instructions from the human-machine interface, and drive the first carrier stage 11, the second carrier stage 12, the actuating unit 13, the rangefinder 14, the image capturing unit 16, the laser light source 17 and other components or units in accordance with preset process parameters or real-time feedback parameter values during the process to operate in a set process. That is, the processing unit 15 can integrate and control the functions of the first carrier stage 11, the second carrier stage 12, the actuating unit 13, the rangefinder 14, the image capturing unit 16, the laser light source 17 and other components or units.

During the period when the actuating unit 13 controls the first carrier stage 11 or the second carrier stage 12 to move in the first direction D1 (Y-axis), the processing unit 15 can transmit the compensation value to the actuating unit 13, so that the actuating unit 13 can change the distance d between the corresponding areas in accordance with the compensation value, thereby performing the real-time dynamic compensation in at least the second direction D2 (Z-axis) on the component substrate 2 and/or the target substrate 3 during the transfer process. In other words, the processing unit 15 can calculate the distance compensation value of the corresponding areas based on the height difference in the second direction D2 (Z-axis) between the position of the microchip 22 in the area on the component substrate 2 and the transfer coordinates of the corresponding area on the target substrate 3 as well as the process settings. Moreover, before the microchip 22 is transferred, the distance in the second direction D2 (Z-axis) between the microchip 22 in the area on the component substrate 2 and the transfer coordinates of the corresponding area on the target substrate 3 can be calibrated in accordance with the compensation value, so that transfer heights in the second direction D2 (Z-axis) of all the microchips 22 arranged in the second direction D2 can be approximate to the same. For example, the variations of the height differences of the microchips 22 are less than 3 microns.

In one embodiment, as shown in FIG. 3, the actuating unit 13 may include at least one piezoelectric actuator 131, which can be disposed on the target substrate 3 or the component substrate 2. When the processing unit 15 transmits the compensation value to the actuating unit 13, the actuating unit 13 can control the current applied to the piezoelectric actuator 131 for compensating the height of the target substrate 3 in the second direction D2 (Z-axis). In one embodiment, a plurality of piezoelectric actuators 131 can be provided to achieve the heights compensations in multiple directions or multiple dimensions.

In one embodiment, the actuating unit 13 may include at least two piezoelectric actuators 131, which may be disposed at two opposite ends respectively on one side of the target substrate 3 away from the component substrate 2 in the first direction D1 (Y-axis). For example, to adjust the distances d in the second direction D2 (Z-axis) between two substrates, two piezoelectric actuators 131 can be respectively installed at two ends, in the first direction D1 (Y-axis), on one side of the target substrate 3 away from the component substrate 2. That is, the two piezoelectric actuators 131 are installed between the target substrate 3 and the second carrier stage 12. The two piezoelectric actuators 131 can vary (or adjust) the distances d between the corresponding areas in accordance with respective current values. In different embodiments, the piezoelectric actuators 131 may be respectively disposed at two ends, in the first direction D1 (Y-axis), on one side of the component substrate 2 away from the target substrate 3. In other embodiments, the piezoelectric actuators 131 may be respectively disposed at two ends on one side of the component substrate 2 away from the target substrate 3 and two ends on one side of the target substrate 3 away from the component substrate 2. The number of the piezoelectric actuators 131 is not limited in the present disclosure.

In one embodiment, two piezoelectric actuators 131 can be installed at two ends, in the third direction D3 (X-axis), of one side of the target substrate 3 away from the component substrate 2 (i.e., between the target substrate 3 and the second carrier stage 12), thereby compensating for the distances d of different corresponding areas along the third direction D3 (X-axis).

In other embodiments, the actuating unit 13 may include more than two piezoelectric actuators 131 (e.g. four or more piezoelectric actuators 131). For example, in order to simultaneously adjust the distances d in the second direction D2 (Z-axis) of the corresponding areas along the first direction D1 (Y-axis) and the third direction D3 (X-axis), at least two piezoelectric actuators 131 can be respectively installed at two opposite ends, in the first direction D1 (Y-axis), on one side of the target substrate 3, and at least two piezoelectric actuators 131 can be respectively installed at two opposite ends, in the third direction D3 (X-axis), on one side of the target substrate 3. This configuration of the piezoelectric actuators 131 can simultaneously adjust the distances d in the second direction D2 (Z-axis) between the two substrates along the first direction D1 (Y-axis) and the third direction D3 (X-axis). In other embodiments, two piezoelectric actuators 131 can be respectively arranged at two ends on one side of the component substrate 2 away from the target substrate 3 in one direction (e.g. the first direction D1 (Y-axis)), and two additional piezoelectric actuators 131 can be respectively arranged at two ends on one side of the target substrate 3 away from the component substrate 2 in another direction (e.g. the third direction D3 (X-axis)). To be noted, this disclosure is not limited thereto.

Referring to FIG. 4A, the microchips 22 of the component substrate 2 are arranged in an array along the first direction D1 (Y-axis) and the third direction D3 (X-axis). When the rangefinder 14 is a line scan mode rangefinder for measuring the distance in the direction D as shown in FIG. 4A, there are a plurality of corresponding areas scanned in each scanning process (i.e., part or all of the coordinate points X1 to Xn). Therefore, the processing unit 15 can obtain a plurality of corresponding compensation values in accordance with the first variation information and the second variation information of each of the plurality of areas and corresponding areas, so that the actuating unit 13 can change the distances d of the plurality of areas and corresponding areas in accordance with the compensation values. As mentioned above, in the line scan mode, these compensation values can be obtained based on arithmetic mean, mode mean, median or quartile mean, or the likes. In one embodiment, multiple microchips 22 having the same Y-axis coordinate in the first direction D1 (Y-axis), such as (Y1, X1), (Y1, X2), . . . , and (Y1, Xn), are provided, and one scanning process of the line scan mode can scan all of these microchips 22 to obtain the compensation values for the distances in the second direction D2 (Z-axis). A plurality of compensation values can be arranged in order to obtain a first quartile (Q₁, the value under which 25% of the coordinate points X1˜Xn are found when they are arranged in increasing order) and the third quartile (Q₃, the value under which 75% of the coordinate points X1˜Xn are found when they are arranged in increasing order). The change (variation) of the distance d in the second direction D2 (Z-axis) of each coordinate point can be between the first quartile (Q₁) and the third quartile (Q₃) of the corresponding compensation value. It should be understandable that the compensation amounts of the corresponding areas in the second direction D2 (Z-axis) may be the same or different.

In one embodiment, as shown in FIG. 4B, the microchips 22 are arranged along the first direction D1 (Y-axis) or the third direction D3 (X-axis), wherein the first variation information further includes a vector of each area on the component substrate 2, the second variation information further includes a vector of each corresponding area on the target substrate 3, and the vectors are in the first direction D1 (Y-axis) or the third direction D3 (X-axis). The actuating unit 13 can control the component substrate 2 and the target substrate 3 to relatively move in the first direction D1 (Y-axis) or the third direction D3 (X-axis) in accordance with the compensation value corresponding to the area and the corresponding area. Specifically, if the microchip 22 disposed on the substrate 21 has horizontal offset (offset in X-axis, offset in Y-axis, or offset in both X-axis and Y-axis), regarding the microchip 22 located within the allowable offset threshold, the distance d between the component substrate 2 and the target substrate 3 can be compensated immediately by relative moving the component substrate 2 and the target substrate 3 in the first direction D1 (Y-axis) and/or the third direction D3 (X-axis) in the dynamic, real-time and on-the-fly mode of the transfer process. On the contrary, regarding the microchip 22 located out of the allowable offset threshold (e.g. the microchip 22 is missing), the transfer process for this microchip 22 can be abandoned, and this problem can be solved by an additional transfer process or a repairing process.

In addition to controlling the movement of the first carrier stage 11 and/or the second carrier stage 12, the actuating unit 13 can also control the rotation of the first carrier stage 11 and/or the second carrier stage 12. In another case, the actuating unit 13 can control the movement and rotation of the first carrier stage 11 and/or the second carrier stage 12. In one embodiment, if the microchip 22 disposed in the area on the component substrate 2 has a horizontal rotation, the first variation information and the second variation information may include a rotation angle of the area on the component substrate 2 and the corresponding area on the target substrate 3 with respect to the second direction D2 (Z-axis). Therefore, the actuating unit 13 can control the first carrier stage 11 and/or the second carrier stage 12 to rotate about the second direction D2 (Z-axis) (i.e., horizontal rotation) in accordance with the compensation value including the rotation angle, thereby providing the rotation compensation for the microchip 22 in the X-axis direction and the Y-axis direction of the microchip 22 itself.

In one embodiment, the component substrate 2 is configured with one or more positioning points for machine alignment. If the measured result of the rangefinder 14 does not match the expected value, it means that the rotation or displacement may be caused by the carrier stages instead of the substrate or chip. For example, as shown in FIG. 4C, if the difference between the height and parallelism of the chips measured in the second direction D2 (Z-axis) is normal (e.g. the height difference between the highest chip and the lowest chip does not exceed 3 microns), but the ranging spots obtained by measuring the chips indicate that the widths of the chips are obviously unequal (as shown in FIG. 4D, the measured widths w1˜w4 of the chips are significantly different), it means that the first carrier stage 11 has horizontal offset. In another case, if the periodically measured heights of the chips in the second direction D2 (Z-axis) are all 0, or the measured values are consistent but obviously abnormal, it also means that the first carrier stage 11 has horizontal offset. In another case, if the carrier stage is tilted (that is, the carrier stage is rotated about the X-axis (see FIG. 4E) or the Y-axis, or the component substrate 2 has uneven thickness or is curved, the following may occur: 1. the period (frequency) of the measured values in the second direction D2 (Z-axis) (i.e., the spacing w1′˜w4′ along the first direction D1) measured by the rangefinder 14 is shorter than the preset value, and the change pattern indicates that one side drops to 0 instantaneously and the other side increases or decreases linearly (as shown in the upper part of FIG. 4E); 2. errors of the ranging values departure from the normal range, and there is an obvious directional trend change in some or all sections (as shown in the lower part of FIG. 4E); and 3. the measured heights of the chips have a linear change (under high-frequency ranging). In accordance with the above characteristics of the measured distances d, the processing unit 15 can determine the compensation modes and compensation values for the corresponding microchips 22 respectively, and the actuating unit 13 then controls the first carrier stage 11 or the second carrier stage 12 to rotate about the first direction D1 (Y-axis), the second direction D2 (Z-axis) or the third direction D3 (X-axis) in accordance with the compensation values.

Referring to FIGS. 4C and 4D, in the above-mentioned case as shown in FIG. 4C, the distances d, which are measured based on the first variation information obtained by ranging the microchips 22 in the area on the component substrate 2 and/or the second variation information obtained by ranging the corresponding area on the target substrate 3, can independently or jointly form a change frequency related to the first direction D1 (Y-axis). More specifically, the values shown in FIG. 4D indicate the distances d in the second direction D2 (Z-axis) obtained based on the first variation information and/or the second variation information, and the distance between multiple corresponding areas in the X-Y plane can affect the widths w1 to w4. In fact, the widths w1 to w4 or their frequency of changes in the first direction D1 (Y-axis) can be used to determine the rotation offset or displacement in the plane parallel to the X-Y plane of the first carrier stage 11 relative to the second carrier stage 12. Therefore, the processing unit 15 can generate each compensation value in accordance with the changing frequency.

Referring to FIG. 3, the image capturing unit 16 is disposed at one side of at least one of the first carrier stage 11 and the second carrier stage 12 in the second direction D2 and electrically connected to the processing unit 15. In other words, the image capturing unit 16 can be disposed between the first carrier stage 11 and the second carrier stage 12, disposed at the upper side of the first carrier stage 11 away from the second carrier stage 12, or disposed at the lower side of the second carrier stage 12 away from the first carrier stage 11, and this disclosure is not limited thereto.

The horizontal offset of the chip as shown in FIG. 4B and the horizontal offset of the stage as shown in FIG. 4C can also be directly measured by the image capturing unit 16. In this embodiment, the image capturing unit 16 is configured for measuring the vector of the area on the component substrate 2 included in the first variation information, and the vector of the corresponding area on the target substrate 3 included in the second variation information. The image capturing unit 16 can retrieve the relative position information of the component substrate 2 and the target substrate 3 in advance, and then moves the stages to compensate the displacement or rotation of the two substrate in the horizontal plane (X-Y plane). After that, the corresponding areas are selected to measure the first variation information and the second variation information of the corresponding areas. To be noted, the aforementioned relative position information includes the displacement information or rotation information of the microchips 22. In one embodiment, the image capturing unit 16 may include a camera with a CCD or CMOS sensing element.

As mentioned above, in the mass transfer equipment 1 of this embodiment, the real-time dynamic compensation in the height direction of the component substrate 2 and/or the target substrate 3 can be performed during the dynamic, real-time and on-the-fly transfer process of the microchips 22 of the component substrate 2. That is, the distance between the microchip 22 of the component substrate 2 and the target substrate 3 in the second direction D2 (Z-axis) can be dynamically adjusted to compensate for the flatness of the equipment. Therefore, the technology of this disclosure can be applied to the mass transfer stage systems with lower flatness and cheaper prices, and can still achieve the effect of stabilizing the height of the spacing (in the Z-axis) between the two substrates. Moreover, the technology of this disclosure is not limited by the size of the carrier stages, and can be applied to the mass transfer process of microchips on large-sized carriers, thereby reducing the equipment cost.

In summary, in the mass transfer equipment of this disclosure, the first carrier stage is configured for carrying the component substrate, and is movable in a first direction, the second carrier stage is configured for carrying the target substrate, and is movable in the first direction, at least one area on the component substrate and a corresponding area on the target substrate are departed by a distance in the second direction, the actuating unit is connected with the first carrier stage and the second carrier stage, and is configured for controlling at least one of the first carrier stage and the second carrier stage to move and/or rotate, the rangefinder is configured for measuring a movement of the component substrate in the first direction to obtain a first variation information and a movement of the target substrate in the first direction to obtain a second variation information, the first variation information includes a vector of the area on the component substrate in the second direction, the second variation information includes a vector of the corresponding area on the target substrate in the second direction, and the processing unit obtains a compensation value based on the first variation information and/or the second variation information. During the actuating unit controlling the first carrier stage or the second carrier stage to move in the first direction, the processing unit further transmits the compensation value to the actuating unit, so that the actuating unit changes the distance in accordance with the compensation value. Therefore, this disclosure can perform real-time dynamic compensation in the height (Z-axis) direction of the component substrate and/or the target substrate during the dynamic, real-time and on-the-fly transfer process of microchips, thereby compensating for the flatness of the equipment. Accordingly, the mass transfer equipment of this disclosure can be applied to a mass transfer stage system with lower flatness and cheaper price, and can still achieve the effect of stabilizing the height of the spacing (in the Z-axis) between two substrates. Moreover, the present disclosure is not limited by the size of the carrier stages, and can be applied to the large-sized carrier stages for performing the mass transfer process of microchips, thereby reducing the cost of transfer equipment.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A mass transfer equipment, which is suitable for transferring a plurality of microchips from a component substrate to a target substrate, comprising:
a first carrier stage configured for carrying the component substrate, wherein the first carrier stage is movable in a first direction;
a second carrier stage disposed opposite to the first carrier stage and configured for carrying the target substrate, wherein the second carrier stage is movable in the first direction, and at least one area on the component substrate and a corresponding area on the target substrate are departed by a distance in a second direction;
an actuating unit connected with the first carrier stage and the second carrier stage and configured for controlling at least one of the first carrier stage and the second carrier stage to move and/or rotate;
a rangefinder configured for measuring a movement of the component substrate in the first direction to obtain a first variation information and a movement of the target substrate in the first direction to obtain a second variation information, wherein the first variation information comprises a vector of the area on the component substrate in the second direction, and the second variation information comprises a vector of the corresponding area on the target substrate in the second direction; and
a processing unit electrically connected with the actuating unit and the rangefinder, wherein the processing unit obtains a compensation value based on the first variation information and/or the second variation information;
wherein, during the actuating unit controlling the first carrier stage or the second carrier stage to move in the first direction, the processing unit further transmits the compensation value to the actuating unit, so that the actuating unit changes the distance in accordance with the compensation value.

2. The mass transfer equipment of claim 1, wherein the processing unit further obtains a plurality of the compensation values based on a plurality of the first variation information corresponding to a plurality of the areas on the component substrate and a plurality of the second variation information corresponding to a plurality of the corresponding areas on the target substrate.

3. The mass transfer equipment of claim 2, wherein the areas and the corresponding areas are arranged in a third direction, the third direction is perpendicular to the first direction and the second direction, and the actuating unit changes a plurality of the distances in accordance with the compensation values.

4. The mass transfer equipment of claim 3, wherein the compensation values comprise a first quartile and a third quartile, and a plurality of variations of the distances in the second direction are between the first quartile of the compensation values and the third quartile of the compensation values.

5. The mass transfer equipment of claim 2, wherein the areas and the corresponding areas are arranged in the first direction or a third direction, and the third direction is perpendicular to the first direction and the second direction;
wherein, any one of the plurality of the first variation information and the plurality of the second variation information further comprises a vector in the first direction or in the third direction, and the actuating unit controls the component substrate and the target substrate to relatively move in the first direction or the third direction in accordance with the compensation value of corresponding one of the plurality of the areas.

6. The mass transfer equipment of claim 2, wherein the actuating unit controls the first carrier stage or the second carrier stage to rotate about the first direction, the second direction or a third direction, and the third direction is perpendicular to the first direction and the second direction.

7. The mass transfer equipment of claim 6, wherein a plurality of the distances obtained in accordance with the plurality of the first variation information or the plurality of the second variation information are relative to a change frequency in the first direction, and the plurality of the compensation values are generated by the processing unit based on the change frequency.

8. The mass transfer equipment of claim 1, wherein the first variation information or the second variation information comprises a rotation angle of the area or the corresponding area with respect to the second direction, and the actuating unit controls the first carrier stage or the second carrier stage to rotate about the second direction in accordance with the compensation value.

9. The mass transfer equipment of claim 1, wherein the actuating unit comprises at least two piezoelectric actuators, the piezoelectric actuators are disposed at two opposite ends respectively on one side of the target substrate away from the component substrate in the first direction or a third direction perpendicular to the first direction and the second direction, and the piezoelectric actuators vary the distance in accordance with the compensation value.

10. The mass transfer equipment of claim 1, further comprising:
an image capturing unit disposed at one side of at least one of the first carrier stage and the second carrier stage in the second direction and electrically connected to the processing unit, wherein the image capturing unit retrieves relative position information of the component substrate and the target substrate in the first direction or a third direction perpendicular to the first direction and the second direction, and the area and the corresponding area are defined by the processing unit based on the relative position information.

11. The mass transfer equipment of claim 10, wherein the image capturing unit is configured for measuring a vector of the area included in the first variation information and a vector of the corresponding area included in the second variation information, wherein the vectors are in the first direction or the third direction.

12. The mass transfer equipment of claim 1, wherein the component substrate comprises at least one microchip disposed on the area on the component substrate, and the first variation information includes a replacement of the at least one microchip in the second direction with respect to the first carrier stage.

13. The mass transfer equipment of claim 1, further comprising:
a laser light source disposed at one side of the first carrier stage and the second carrier stage, wherein the laser light source has a light axis;
wherein the actuating unit controls the first carrier stage and the second carrier stage to move simultaneously in the first direction, so that the area on the component substrate is aligned with the light axis and focused by the laser light source.

14. The mass transfer equipment of claim 13, wherein the rangefinder and the laser light source are relatively fixed with respect to the first carrier stage and the second carrier stage.
